(19) United States
(12) Patent Application Publication
(10) Pub. No.: US 2026/0082904 A1
(43) Pub. Date: Mar. 19, 2026

(54) SEMICONDUCTOR DEVICE

(71) Applicant: Renesas Electronics Corporation, Tokyo (JP)

(72) Inventors: Makoto KOSHIMIZU, Tokyo (JP); Yasutaka NAKASHIBA, Tokyo (JP)

(21) Appl. No.: 19/267,745

(22) Filed: Jul. 14, 2025

(30) Foreign Application Priority Data
Sep. 19, 2024 (JP) 2024-162290

(51) Int. Cl. H01L 23/522; H01L 23/10; H01L 23/528; H01L 23/532

(52) U.S. Cl. CPC H10W 20/496; H10W 20/435; H10W 20/4407; H10W 20/4451; H10W 76/60

(57) ABSTRACT

A semiconductor device of the present disclosure includes a semiconductor substrate having an element formation portion and a composite capacitor formed to surround the element formation portion in plan view. The composite capacitor has a plurality of capacitor elements electrically connected in parallel.

### CROSS-REFERENCE TO RELATED APPLICATIONS

The disclosure of Japanese Patent Application No. 2024-162290 filed on Sep. 19, 2024, including the specification, drawings and abstract is incorporated herein by reference in its entirety.

### BACKGROUND

This disclosure relates to a semiconductor device.

There are disclosed techniques listed below. [Patent Document 1] Japanese Unexamined Patent Application Publication No. 2017-174887

Patent Document 1 discloses a semiconductor device. Patent Document 1 discloses a semiconductor device having a semiconductor substrate, a polysilicon layer, and an insulating film. A trench is formed at the upper surface of the semiconductor substrate. The semiconductor substrate has a well layer. The well layer is formed in the semiconductor substrate and is formed at the upper surface of the semiconductor substrate so as to surround the trench. The polysilicon layer is formed in the trench. The insulating film is positioned between the polysilicon layer and the inner wall surface and the bottom surface of the trench. The well layer, the polysilicon layer, and the insulating film positioned between the well layer and the polysilicon layer configure a trench capacitor.

### SUMMARY

When the trench capacitor formed inside the outer peripheral edge of the element formation portion of the semiconductor substrate in plan view, the area of the element formation portion must be increased in plan view, resulting in an increase in the chip area of the semiconductor device. Other problems and novel features will become apparent from the description herein and the accompanying drawings.

A semiconductor device of this disclosure includes a semiconductor substrate having an element formation portion and a composite capacitor formed to surround the element formation portion in plan view. The composite capacitor includes a plurality of capacitor elements electrically connected in parallel.

According to the semiconductor device of this disclosure, it is possible to form a plurality of capacitor elements monolithically without increasing the chip area.

### BRIEF DESCRIPTION OF THE DRAWINGS

FIG. 1 is a plan view of a semiconductor device DEV1.

FIG. 2 is a cross-sectional view of the semiconductor device DEV1 along II-II in FIG. 1.

FIG. 3 is a schematic equivalent circuit diagram of a composite capacitor CC.

FIG. 4A is a schematic layout diagram of a plurality of circuits included in the semiconductor device DEV1.

FIG. 4B is a circuit diagram of a bootstrap circuit.

FIG. 5 is a step diagram of a manufacturing step of the semiconductor device DEV1.

FIG. 6 is a cross-sectional view explaining the ion implantation step S2.

FIG. 7 is a cross-sectional view explaining the first insulating film formation step S3.

FIG. 8 is a cross-sectional view explaining the first wiring formation step S4.

FIG. 9 is a cross-sectional view explaining the second insulating film formation step S5.

FIG. 10 is a cross-sectional view explaining the second wiring formation step S6.

FIG. 11 is a cross-sectional view explaining the interlayer insulating film formation step S7.

FIG. 12 is a cross-sectional view explaining the plug formation step S8.

FIG. 13 is a cross-sectional view explaining the third wiring formation step S9.

FIG. 14 is a plan view of the semiconductor device DEV1 according to a modified example.

FIG. 15 is a cross-sectional view of the semiconductor device DEV1 according to the modified example along XV-XV in FIG. 14.

FIG. 16 is a cross-sectional view of a semiconductor device DEV2.

FIG. 17 is an equivalent circuit diagram of the composite capacitor CC in the semiconductor device DEV2.

### DETAILED DESCRIPTION

The details of the embodiments of this disclosure will be described with reference to the drawings. In the following drawings, the same or corresponding parts are denoted by the same reference numerals, and redundant explanations will not be repeated.

### First Embodiment

The semiconductor device DEV1 according to the first embodiment will be described.

### Configuration of Semiconductor Device DEV1

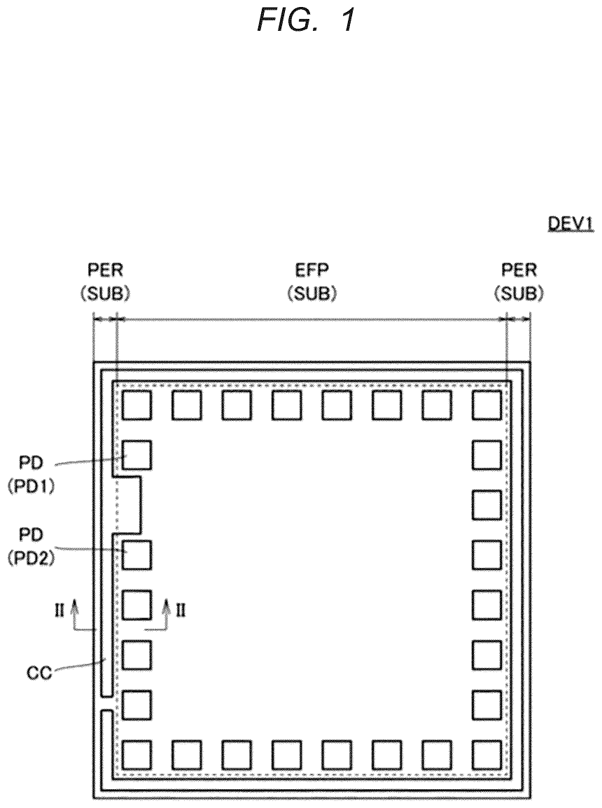

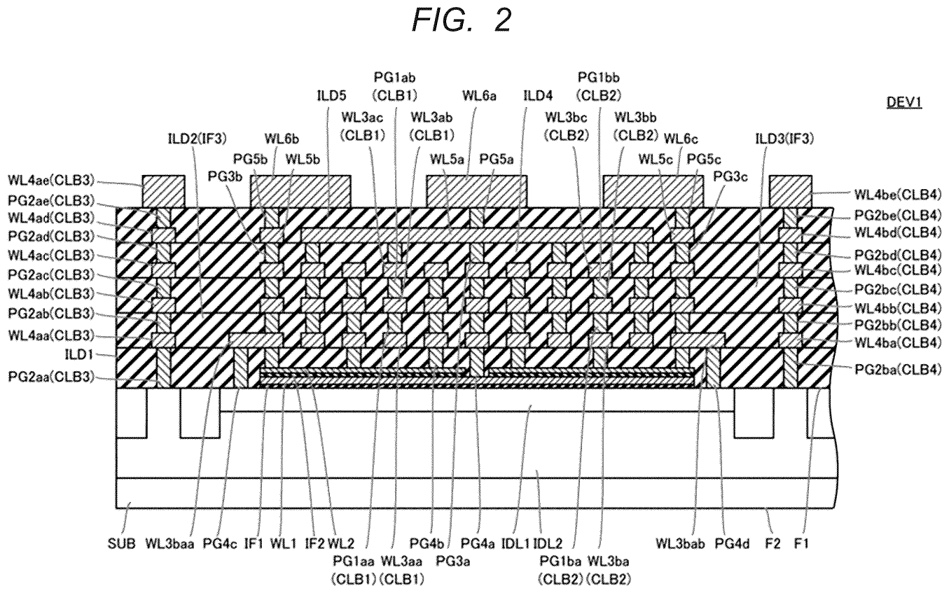

As shown in FIGS. 1 and 2, the semiconductor device DEV1 includes the semiconductor substrate SUB. The semiconductor substrate SUB has the upper surface F1 and the lower surface F2 located on the opposite side of the upper surface F1. The semiconductor substrate SUB, in plan view, includes the element formation portion EFP and the outer peripheral portion PER surrounding the element formation portion EFP. The semiconductor substrate SUB is formed of, for example, single crystal silicon. The semiconductor device DEV1 further includes the composite capacitor CC. The composite capacitor CC surrounds the element formation portion EFP in plan view. From another perspective, the composite capacitor CC overlaps the outer peripheral portion PER in plan view.

The composite capacitor CC includes the impurity diffusion layer IDL1 and the impurity diffusion layer IDL2. The impurity diffusion layer IDL1 and the impurity diffusion layer IDL2 are formed in the semiconductor substrate SUB. The impurity diffusion layer IDL1 is positioned at the upper surface F1. The impurity diffusion layer IDL2 is positioned under the impurity diffusion layer IDL1 so as to contact the impurity diffusion layer IDL1. However, a part of the impurity diffusion layer IDL2 is positioned at the upper surface F1. The conductivity type of the impurity diffusion layer IDL1 is opposite to the conductivity type of the impurity diffusion layer IDL2. For example, if the conductivity type of the impurity diffusion layer IDL1 is p-type, the conductivity type of the impurity diffusion layer IDL2 is n-type.

The composite capacitor CC further includes the insulation film IF1. The insulation film IF1 is formed on the upper surface F1 so as to overlap the impurity diffusion layer IDL1 in plan view. The insulation film IF1 is formed of, for example, silicon oxide. The semiconductor device DEV1 further includes the wiring WL1. The wiring WL1 is formed on the insulating film IF1. From another perspective, the insulation film IF1 is positioned between the wiring WL1 and the impurity diffusion layer IDL1. The wiring WL1 is formed of, for example, polycrystalline silicon containing dopants.

The composite capacitor CC further includes an insulating film IF2. The insulating film IF2 is formed on the wiring WL1. The insulation film IF2 includes, for example, a first silicon oxide film, a silicon nitride film formed on the first silicon oxide film, and a second silicon oxide film formed on the silicon nitride film. From another perspective, the insulating film IF2 is an ONO (Oxide Nitride Oxide) film.

The composite capacitor CC further includes a wiring WL2. The wiring WL2 is formed on the insulating film IF2. From another perspective, the insulating film IF2 is positioned between the wiring WL2 and the wiring WL1. The wiring WL2 is formed of, for example, a metal silicide such as tungsten silicide.

The semiconductor device DEV1 further includes an interlayer insulating film ILD1, an interlayer insulating film ILD2, an interlayer insulating film ILD3, an interlayer insulating film ILD4, and an interlayer insulating film ILD5. The interlayer insulating film ILD1 is formed on the upper surface F1 so as to cover the insulating film IF1, the wiring WL1, the insulating film IF2, and the wiring WL2. The interlayer insulating film ILD2 is formed on the interlayer insulating film ILD1. The interlayer insulating film ILD3 is formed on the interlayer insulating film ILD2. The interlayer insulating film ILD4 is formed on the interlayer insulating film ILD3. The interlayer insulating film ILD5 is formed on the interlayer insulating film ILD4. The interlayer insulating film ILD1, the interlayer insulating film ILD2, the interlayer insulating film ILD3, the interlayer insulating film ILD4, and the interlayer insulating film ILD5 are formed of, for example, silicon oxide.

The composite capacitor CC further includes an insulating film IF3, a plurality of conductive laminates CLB1, and a plurality of conductive laminates CLB2. The insulating film IF3 includes the interlayer insulating film ILD2 and the interlayer insulating film ILD3. The plurality of conductive laminates CLB1 and the plurality of conductive laminates CLB2 are formed in the insulating film IF3.

Each of the plurality of conductive laminates CLB1 includes a wiring WL3aa, a wiring WL3ab, a wiring WL3ac, a plug PG1aa, and a plug PG1ab. The wiring WL3aa is formed on the interlayer insulating film ILD1 and is covered by the interlayer insulating film ILD2. The wiring WL3ab is formed on the interlayer insulating film ILD2 and is covered by the interlayer insulating film ILD3. The wiring WL3ac is formed on the interlayer insulating film ILD3 and is covered by the interlayer insulating film ILD4. The wiring WL3aa, the wiring WL3ab, and the wiring WL3ac extend along the outer peripheral portion PER in plan view. The wiring WL3aa, the wiring WL3ab, and the wiring WL3ac overlap each other in plan view.

The plug PG1aa and the plug PG1ab extend along the outer peripheral portion PER in plan view. The plug PG1aa is formed in the interlayer insulating film ILD2. The plug PG1aa is positioned between the wiring WL3aa and the wiring WL3ab, connecting the wiring WL3aa and the wiring WL3ab. The plug PG1ab is formed in the interlayer insulating film ILD3. The plug PG1ab is positioned between the wiring WL3ab and the wiring WL3ac, connecting the wiring WL3ab and the wiring WL3ac. The plug PG1aa and the plug PG1ab overlap each other in plan view. In this way, each of the plurality of conductive laminates CLB1 includes a plurality of wirings and a plurality of plugs, and the plurality of wirings are laminated such that one of the plurality of plugs positioned between two wirings of the plurality of wirings adjacent to each other.

Each of the plurality of conductive laminates CLB2 includes a wiring WL3ba, a wiring WL3bb, a wiring WL3bc, a plug PG1ba, and a plug PG1bb. The wiring WL3ba is formed on the interlayer insulating film ILD1 and is covered by the interlayer insulating film ILD2. The wiring WL3bb is formed on the interlayer insulating film ILD2 and is covered by the interlayer insulating film ILD3. The wiring WL3bc is formed on the interlayer insulating film ILD3 and is covered by the interlayer insulating film ILD4. The wiring WL3ba, the wiring WL3bb, and the wiring WL3bc extend along the outer peripheral portion PER in plan view. The wiring WL3ba, the wiring WL3bb, and the wiring WL3bc overlap each other in plan view.

The plug PG1ba and the plug PG1bb extend along the outer peripheral portion PER in plan view. The plug PG1ba is formed in the interlayer insulating film ILD2. The plug PG1ba is positioned between the wiring WL3ba and the wiring WL3bb, connecting the wiring WL3ba and the wiring WL3bb. The plug PG1bb is formed in the interlayer insulating film ILD3. The plug PG1bb is positioned between the wiring WL3bb and the wiring WL3bc, connecting the wiring WL3bb and the wiring WL3bc. The plug PG1ba and the plug PG1bb overlap each other in plan view. In this manner, each of the plurality of conductive laminates CLB2 has a plurality of wirings and a plurality of plugs, and the plurality of wirings are laminated such that one of the plurality of plugs positioned between two wirings of the plurality of wirings adjacent to each other.

The wiring WL3aa, the wiring WL3ab, and the wiring WL3ac are formed, for example, of aluminum or aluminum alloy. The plug PG1aa and the plug PG1ab are formed, for example, of tungsten. The wiring WL3ba, the wiring WL3bb, and the wiring WL3bc are formed, for example, of aluminum or an aluminum alloy. The plug PG1ba and the plug PG1bb are formed, for example, of tungsten.

The conductive laminate CLB1 and the conductive laminate CLB2 are alternately arranged with a gap between them along the direction from the inner peripheral edge to the outer peripheral edge of the outer peripheral portion PER. From another perspective, a part of the insulating film IF3 is disposed between the conductive laminate CLB1 and the conductive laminate CLB2 adjacent to each other.

The semiconductor device DEV1 further includes a conductive laminate CLB3. The conductive laminate CLB3 surrounds the composite capacitor CC in plan view. The conductive laminate CLB3 includes a wiring WL4aa, a wiring WL4ab, a wiring WL4ac, a wiring WL4ad, and a wiring WL4ae, as well as a plug PG2aa, a plug PG2ab, a plug PG2ac, a plug PG2ad, and a plug PG2ae.

The wiring WL4aa, the wiring WL4ab, the wiring WL4ac, the wiring WL4ad, and the wiring WL4ae extend along the outer peripheral portion PER in plan view. The wiring WL4aa is formed on the interlayer insulating film ILD1 and covered by the interlayer insulating film ILD2. The wiring WL4ab is formed on the interlayer insulating film ILD2 and covered by the interlayer insulating film ILD3. The wiring WL4ac is formed on the interlayer insulating film ILD3 and covered by the interlayer insulating film ILD4. The wiring WL4ad is formed on the interlayer insulating film ILD4 and covered by the interlayer insulating film ILD5. The wiring WL4ae is formed on the interlayer insulating film ILD5. The wiring WL4aa, the wiring WL4ab, the wiring WL4ac, the wiring WL4ad, and the wiring WL4ae overlap each other in plan view.

The plug PG2aa, the plug PG2ab, the plug PG2ac, the plug PG2ad, and the plug PG2ae extend along the outer peripheral portion PER in plan view. The plug PG2aa is formed in the interlayer insulating film ILD1. The plug PG2aa is positioned between the wiring WL4aa and the semiconductor substrate SUB, connecting the wiring WL4aa and the impurity diffusion layer IDL2. The plug PG2ab is formed in the interlayer insulating film ILD2. The plug PG2ab is positioned between the wiring WL4aa and the wiring WL4ab, connecting the wiring WL4aa and the wiring WL4ab.

The plug PG2ac is formed in the interlayer insulating film ILD3. The plug PG2ac is positioned between the wiring WL4ab and the wiring WL4ac, connecting the wiring WL4ab and the wiring WL4ac. The plug PG2ad is formed in the interlayer insulating film ILD4. The plug PG2ad is positioned between the wiring WL4ac and the wiring WL4ad, connecting the wiring WL4ac and the wiring WL4ad. The plug PG2ae is formed in the interlayer insulating film ILD5. The plug PG2ae is positioned between the wiring WL4ad and the wiring WL4ae, connecting the wiring WL4ad and the wiring WL4ae. The plug PG2aa, the plug PG2ab, the plug PG2ac, the plug PG2ad, and the plug PG2ae overlap each other in plan view. In this manner, the conductive laminate CLB3 has a plurality of wirings and a plurality of plugs, and the plurality of wirings are laminated such that one of the plurality of plugs is positioned between two wirings of the plurality of wirings adjacent to each other and between the upper surface F1 and one wiring of the plurality of wirings positioned at the lowermost layer.

The wiring WL4aa, the wiring WL4ab, the wiring WL4ac, the wiring WL4ad, and the wiring WL4ae are formed, for example, of aluminum or an aluminum alloy. The plug PG2aa, the plug PG2ab, the plug PG2ac, the plug PG2ad, and the plug PG2ae are formed, for example, of tungsten.

The semiconductor device DEV1 further includes a conductive laminate CLB4. The conductive laminate CLB4 is surrounded by the composite capacitor CC in plan view. The conductive laminate CLB4 includes a wiring WL4ba, a wiring WL4bb, a wiring WL4bc, a wiring WL4bd, and a wiring WL4be, as well as a plug PG2ba, a plug PG2bb, a plug PG2bc, a plug PG2bd, and a plug PG2be.

The wiring WL4ba, the wiring WL4bb, the wiring WL4bc, the wiring WL4bd, and the wiring WL4be extend along the outer peripheral portion PER in plan view. The wiring WL4ba is formed on the interlayer insulating film ILD1 and covered by the interlayer insulating film ILD2. The wiring WL4bb is formed on the interlayer insulating film ILD2 and covered by the interlayer insulating film ILD3. The wiring WL4bc is formed on the interlayer insulating film ILD3 and covered by the interlayer insulating film ILD4. The wiring WL4bd is formed on the interlayer insulating film ILD4 and covered by the interlayer insulating film ILD5. The wiring WL4be is formed on the interlayer insulating film ILD5. The wiring WL4ba, the wiring WL4bb, the wiring WL4bc, the wiring WL4bd, and the wiring WL4be overlap each other in plan view.

The plug PG2ba, the plug PG2bb, the plug PG2bc, the plug PG2bd, and the plug PG2be extend along the outer peripheral portion PER in plan view. The plug PG2ba is formed in the interlayer insulating film ILD1. The plug PG2ba is positioned between the wiring WL4ba and the semiconductor substrate SUB, connecting the wiring WL4ba and the impurity diffusion layer IDL2. The plug PG2bb is formed in the interlayer insulating film ILD2. The plug PG2bb is positioned between the wiring WL4ba and the wiring WL4bb, connecting the wiring WL4ba and the wiring WL4bb.

The plug PG2bc is formed in the interlayer insulating film ILD3. The plug PG2bc is positioned between the wiring WL4bb and the wiring WL4bc, connecting the wiring WL4bb and the wiring WL4bc. The plug PG2bd is formed in the interlayer insulating film ILD4. The plug PG2bd is positioned between the wiring WL4bc and the wiring WL4bd, connecting the wiring WL4bc and the wiring WL4bd. The plug PG2be is formed in the interlayer insulating film ILD5. The plug PG2be is positioned between the wiring WL4bd and the wiring WL4be, connecting the wiring WL4bd and the wiring WL4be. The plug PG2ba, the plug PG2bb, the plug PG2bc, the plug PG2bd, and the plug PG2be overlap each other in plan view. In this manner, the conductive laminate CLB4 has a plurality of wirings and a plurality of plugs, and the plurality of wirings are laminated such that one of the plurality of plugs is positioned between two wirings of the plurality of wirings adjacent to each other and between the upper surface F1 and one wiring of the plurality of wirings positioned at the lowermost layer.

The wiring WL4ba, the wiring WL4bb, the wiring WL4bc, the wiring WL4bd, and the wiring WL4be are formed, for example, of aluminum or an aluminum alloy. The plug PG2ba, the plug PG2bb, the plug PG2bc, the plug PG2bd, and the plug PG2be are formed, for example, of tungsten.

The semiconductor device DEV1 further includes a wiring WL5a and a plurality of plugs PG3a. The wiring WL5a is formed on the interlayer insulating film ILD4 and covered by the interlayer insulating film ILD5. The wiring WL5a extends along the outer peripheral portion PER in plan view and overlaps the plurality of conductive laminate CLB1 and the plurality of conductive laminate CLB2. However, the wiring WL5a does not overlap the conductive laminate CLB2 positioned closest to the outer peripheral edge of the outer peripheral portion PER in plan view, nor does it overlap the conductive laminate CLB2 positioned closest to the inner peripheral edge of the outer peripheral portion PER. The plurality of plugs PG3a are formed in the interlayer insulating film ILD4. Each of the plurality of plugs PG3a connects the wiring WL5a and each wiring WL3ac of the plurality of conductive laminates CLB1. The wiring WL5a is formed, for example, of aluminum or an aluminum alloy, and the plurality of plugs PG3a are formed, for example, of tungsten.

The semiconductor device DEV1 further includes a wiring WL5b and a wiring WL5c, as well as a plug PG3b and a plug PG3c. The wiring WL5b and the wiring WL5c are formed on the interlayer insulating film ILD4 and are covered by the interlayer insulating film ILD5. In plan view, the wiring WL5b overlaps the conductive laminate CLB2, which is closest to the outer peripheral edge of the outer peripheral portion PER, and the wiring WL5c overlaps the conductive laminate CLB2, which is closest to the inner peripheral edge of the outer peripheral portion PER. Additionally, the plug PG3b and the plug PG3c are formed in the interlayer insulating film ILD4.

The plug PG3b is positioned between the wiring WL3bc of the conductive laminate CLB2, which is closest to the outer peripheral edge of the outer peripheral portion PER, and the wiring WL5b, connecting the wiring WL3bc and the wiring WL5b. The plug PG3c is positioned between the wiring WL3bc of the conductive laminate CLB2, which is closest to the inner peripheral edge of the outer peripheral portion PER, and the wiring WL5c, connecting the wiring WL3bc and the wiring WL5c.

The wiring WL5b and the wiring WL5c are formed of aluminum or aluminum alloy, for example, and the plug PG3b and the plug PG3c are formed of tungsten, for example.

The semiconductor device DEV1 further includes a plug PG4a. The plug PG4a is formed in the interlayer insulating film ILD1. The plug PG4a is positioned between one wiring WL3aa of the conductive laminate CLB1 and the wiring WL1, connecting one wiring WL3aa of the conductive laminate CLB1 and the wiring WL1. The plug PG4a is formed of tungsten, for example.

The semiconductor device DEV1 further includes a plurality of plugs PG4b. Each of the plurality of plugs PG4b is formed in the interlayer insulating film ILD1. Each plug PG4b is positioned between the wiring WL3ba of each of the plurality of conductive laminates CLB2 and the wiring WL2, connecting the wiring WL3ba of each of the plurality of conductive laminates CLB2 and the wiring WL2. The plurality of plugs PG4b are formed of tungsten, for example.

The semiconductor device DEV1 further includes a plug PG4c and a plug PG4d. The Wiring WL3ba of the conductive laminate CLB2, which is closest to the outer peripheral edge of the outer peripheral portion PER, has a protrusion WL3baa extending toward the outer peripheral edge. The wiring WL3ba of the conductive laminate CLB2, which is closest to the inner peripheral edge of the outer peripheral portion PER, has a protrusion WL3bab extending toward the inner peripheral edge.

The plug PG4c overlaps the protrusion WL3baa in plan view. The plug PG4c is formed in the interlayer insulating film ILD1. The plug PG4c is positioned between the protrusion WL3baa and the impurity diffusion layer IDL1, connecting the protrusion WL3baa and the impurity diffusion layer IDL1. The plug PG4d is formed in the interlayer insulating film ILD1. The plug PG4d overlaps the protrusion WL3bab in plan view. The plug PG4d is positioned between the protrusion WL3bab and the impurity diffusion layer IDL1, connecting the protrusion WL3bab and the impurity diffusion layer IDL1. The plug PG4c and the plug PG4d are formed of tungsten, for example.

The semiconductor device DEV1 further includes a wiring WL6a, a wiring WL6b, and a wiring WL6c, as well as a plug PG5a, a plug PG5b, and a plug PG5c. The wiring WL6a, the wiring WL6b, and the wiring WL6c are formed on the interlayer insulating film ILD5. In plan view, the wiring WL6a overlaps the wiring WL5a. In plan view, the wiring WL6b partially overlaps the wiring WL5b, and the wiring WL6c partially overlaps the wiring WL5c and the conductive laminate CLB2.

The plug PG5a, the plug PG5b, and the plug PG5c are formed in the interlayer insulating film ILD5. The plug PG5a is positioned between the wiring WL6a and the wiring WL5a, connecting the wiring WL6a and the wiring WL5a. The plug PG5b is positioned between the wiring WL6b and the wiring WL5b, connecting the wiring WL6b and the wiring WL5b. The plug PG5c is positioned between the wiring WL6c and the wiring WL5c, connecting the wiring WL6c and the wiring WL5c.

The wiring WL6a, the wiring WL6b, and the wiring WL6c are formed of aluminum or aluminum alloy, for example. The plug PG5a, the plug PG5b, and the plug PG5c are formed of tungsten, for example.

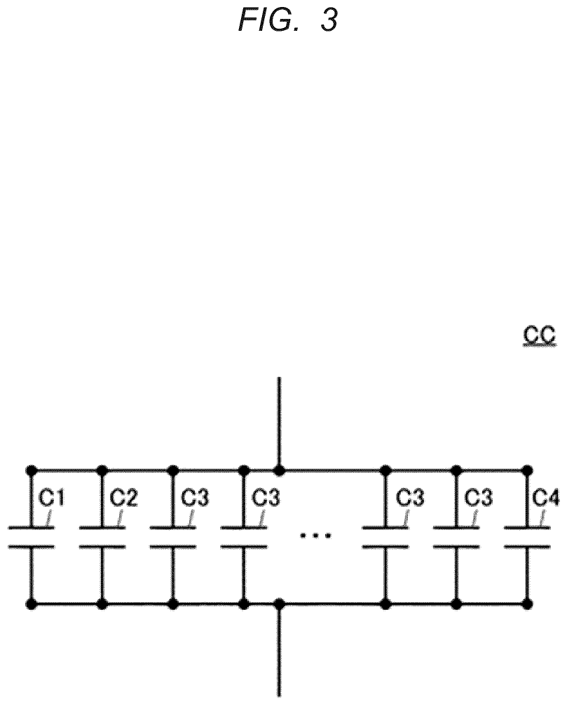

The composite capacitor CC has a plurality of capacitor elements. More specifically, as shown in FIG. 3, the composite capacitor CC includes a capacitor element C1, a capacitor element C2, a capacitor element C3, and a capacitor element C4. The capacitor element C1 includes the impurity diffusion layer IDL1, the insulating film IF1, and the wiring WL1. The capacitor element C2 includes the wiring WL1, the insulation film IF2, and the wiring WL2. The capacitor element C3 includes the conductive laminate CLB1 and the conductive laminate CLB2 adjacent to each other, and a part of the insulating film IF3 positioned between the conductive laminate CLB1 and the conductive laminate CLB2 adjacent to each other. The capacitor element C4 includes the impurity diffusion layer IDL1 and the impurity diffusion layer IDL2. The composite capacitor CC may include at least two of the capacitor element C1, the capacitor element C2, the capacitor element C3, and the capacitor element C4.

The capacitor element C1, the capacitor element C2, the capacitor element C3, and the capacitor element C4 are connected in parallel. A first potential is applied to the wiring WL6a, the wiring WL4ae, and the wiring WL4be, while a second potential different from the first potential is applied to the wiring WL6b and the wiring WL6c. This allows charge to be accumulated in the composite capacitor CC. The width of the composite capacitor CC is measured between the center of the wiring WL4ae and the center of the wiring WL4be in the direction from the inner peripheral edge to the outer peripheral edge of the outer peripheral portion PER. The length of the composite capacitor CC is measured along the direction in which the outer peripheral portion PER extends in plan view. The area of the composite capacitor CC in plan view is the product of the length and the width. The capacitance per unit area of the composite capacitor CC, i.e., the capacitance of the composite capacitor CC divided by the above area, is, for example, between 3.3 nF/mm² and 4 nF/mm².

As shown in FIG. 1, the semiconductor device DEV1 has a plurality of pads PD. The plurality of pads PD are formed on the interlayer insulating film ILD5. The plurality of pads PD are arranged in a row along the outer peripheral edge of the element formation portion EFP. The plurality of pads PD are formed of aluminum or aluminum alloy, for example. A pad PD1 and a pad PD2 of the plurality of pads PD adjacent to each other are arranged with a gap between the pad PD1 and the pad PD2. A part of the composite capacitor CC may be positioned between the pad PD1 and the PD2 in plan view. A part of the composite capacitor CC may be formed under the plurality of pads PD so as to overlap the plurality of pads PD in plan view.

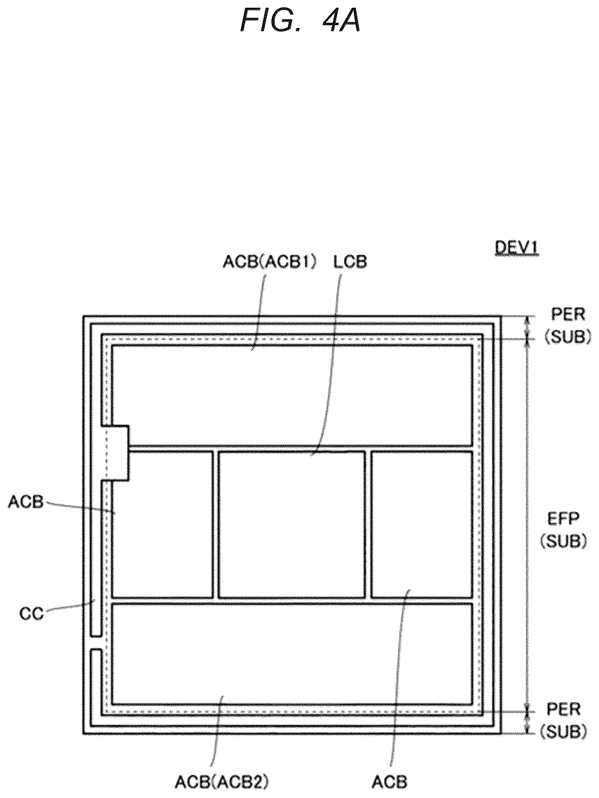

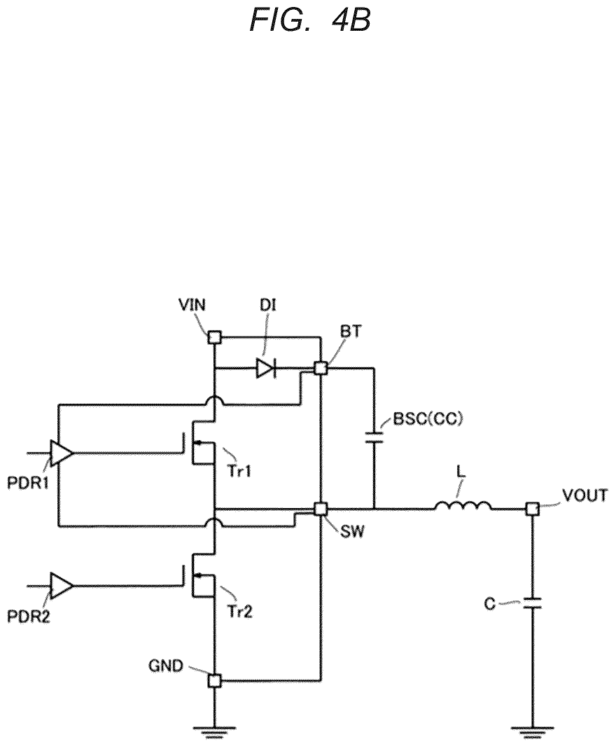

As shown in FIG. 4A, the semiconductor device DEV1 includes, for example, a logic circuit block LCB and a plurality of analog circuit blocks ACB. The logic circuit block LCB and the plurality of analog circuit blocks ACB are arranged inside the outer peripheral edge of the element formation portion EFP so that the logic circuit block LCB is surrounded by the plurality of analog circuit blocks ACB in plan view. From another perspective, the plurality of analog circuit blocks ACB are arranged along the outer peripheral edge of the element formation portion EFP in plan view.

Among the plurality of analog circuit blocks ACB, an analog circuit block ACB1 is a block of analog circuits including a plurality of LDMOS (Laterally Diffused Metal Oxide Semiconductor) transistors, for example. The analog circuit included in the analog circuit block ACB1 is a bootstrap circuit, for example. As shown in FIG. 4B, the bootstrap circuit includes a transistor Tr1 and a transistor Tr2. The source of transistor Tr1 is connected to the drain of transistor Tr2. That is, the transistor Tr1 is connected in series with the transistor Tr2. The source of transistor Tr1 and the drain of transistor Tr2 are connected to the switch terminal SW.

The drain of transistor Tr1 is connected to the input terminal VIN. The source of transistor Tr2 is connected to the ground terminal GND. The input terminal VIN is connected to the boot terminal BT. The boot terminal BT is connected to the switch terminal SW. The ground terminal GND is connected to the switch terminal SW. The bootstrap circuit further includes an inductor L and a capacitor C. The inductor L connects the switch terminal SW and the output terminal VOUT. The capacitor C connects the output terminal VOUT and the ground potential.

The bootstrap circuit further includes a diode DI. The anode of the diode DI is connected between the input terminal VIN and the drain of the transistor Tr1, and the cathode of the diode DI is connected to the boot terminal BT. The bootstrap circuit further includes a pre-driver PRD1 and a pre-driver PRD2. The pre-driver PRD1 is connected to the gate of the transistor Tr1, the boot terminal BT, and the switch terminal SW. The pre-driver PRD2 is connected to the gate of transistor Tr2. The bootstrap circuit further includes a bootstrap capacitor BSC. One electrode of the bootstrap capacitor BSC is connected to the boot terminal BT, and the other electrode of the bootstrap capacitor BSC is connected between the switch terminal SW and the inductor L.

In the first state, the transistor Tr2 is set to be turned on. As a result, the switch terminal SW is at ground potential, and the potential of the input terminal VIN is applied to the bootstrap capacitor BSC via the diode DI and the boot terminal BT, thereby charging the bootstrap capacitor BSC. In the second state, the transistor Tr2 is set to be turned off. As a result, the potential of the boot terminal BT becomes higher than the potential of the input terminal VIN, and the charge is discharged from the charged bootstrap capacitor BSC, turning the transistor Tr1 on. The bootstrap circuit operates by alternating between the first state and the second state.

The composite capacitor CC is connected to the plurality of analog circuit blocks ACB. The composite capacitor CC is connected, for example, to the analog circuit block ACB1 and used as the bootstrap capacitor BSC of the bootstrap circuit. Among the plurality of analog circuit blocks ACB, the analog circuit block ACB2 is, for example, a circuit block that includes a small-signal analog circuit. The analog circuit block ACB1 and the analog circuit block ACB2 are arranged so as not to be adjacent in plan view. For instance, in plan view, the logic circuit block LCB is positioned between the analog circuit block ACB1 and the analog circuit block ACB2.

The composite capacitor CC may be divided. For example, the composite capacitor CC is divided at one location facing the analog circuit block ACB2 in plan view. The composite capacitor CC may be divided at two or more locations. For instance, the portion of the composite capacitor CC surrounding the analog circuit block ACB1 in plan view may be separated from the portion surrounding the analog circuit block ACB2 in plan view.

### Manufacturing Method of Semiconductor Device DEV1

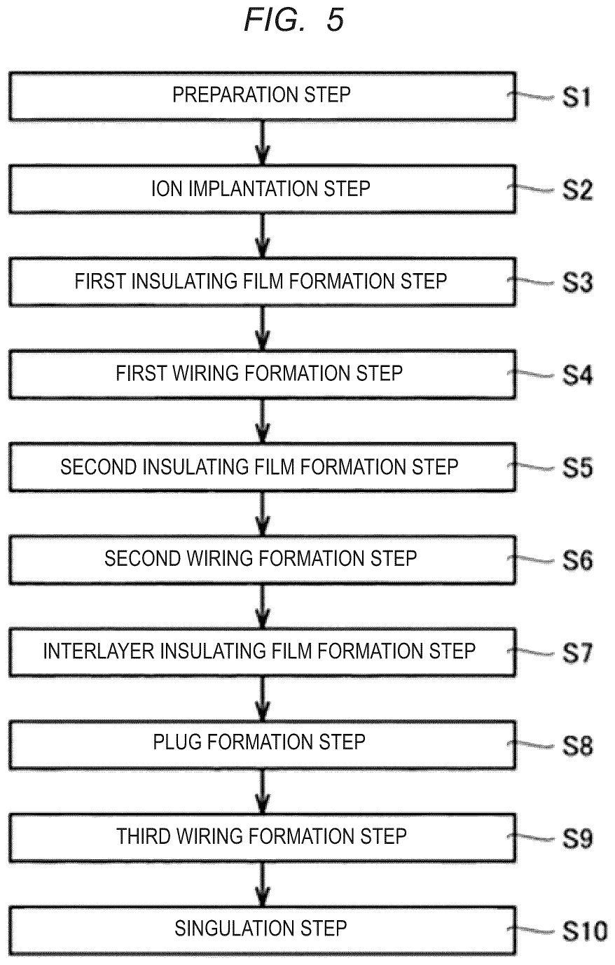

As shown in FIG. 5, the manufacturing method of the semiconductor device DEV1 includes a preparation step S1, an ion implantation step S2, a first insulating film formation step S3, a first wiring formation step S4, a second insulating film formation step S5, a second wiring formation step S6, an interlayer insulating film formation step S7, a plug formation step S8, a third wiring formation step S9, and a singulation step S10.

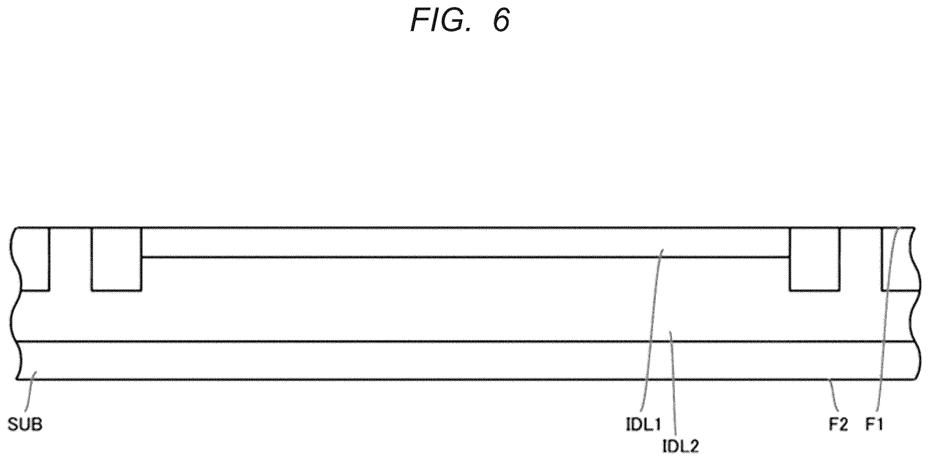

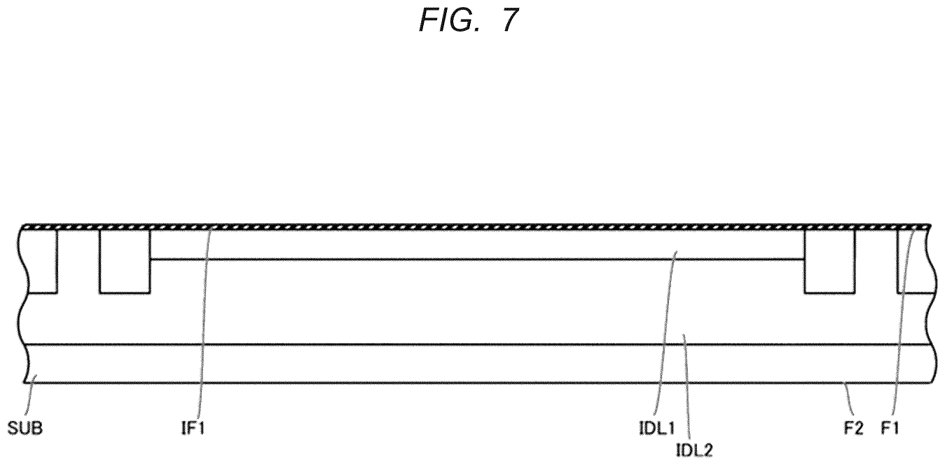

In the preparation step S1, the semiconductor substrate SUB is prepared. As shown in FIG. 6, in the ion implantation step S2, ion implantation is performed to form the impurity diffusion layer IDL1 and the impurity diffusion layer IDL2 in the semiconductor substrate SUB located at the peripheral portion PER. As shown in FIG. 7, in the first insulating film formation step S3, for example, thermal oxidation is performed to form the insulating film IF1 on the upper surface F1 located at the peripheral portion PER.

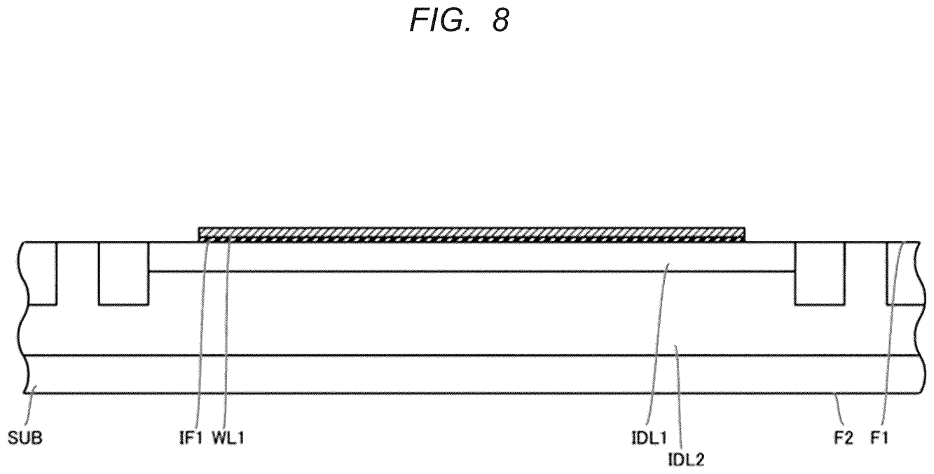

As shown in FIG. 8, in the first wiring formation step S4, the wiring WL1 is formed on the insulating film IF1. In the first wiring formation step S4, firstly, for example, by the CVD (Chemical Vapor Deposition) method, the material constituting the wiring WL1 is formed on the insulating film IF1. Secondly, a resist pattern is formed on the material constituting the wiring WL1. The resist pattern is formed by applying photoresist on the material constituting the wiring WL1 and then exposing and developing the photoresist. Thirdly, dry etching is performed on the material constituting the wiring WL1 through the openings of the resist pattern, patterning the material constituting the wiring WL1 and forming the wiring WL1.

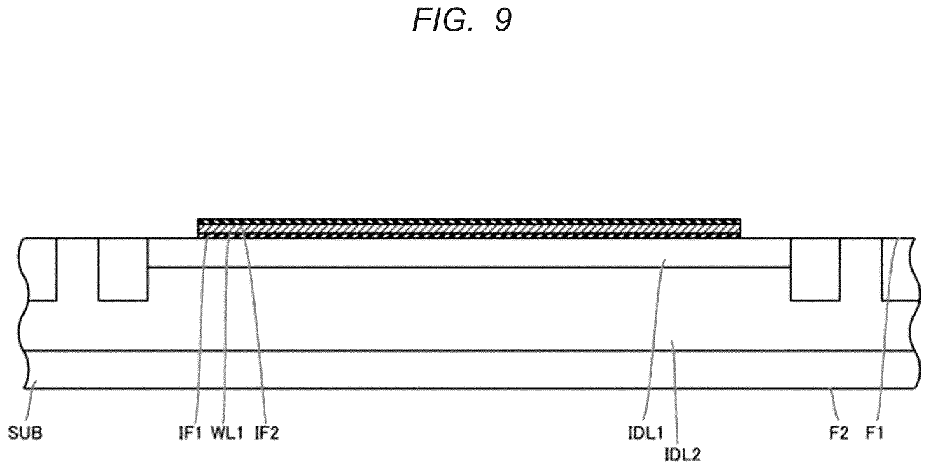

As shown in FIG. 9, in the second insulating film formation step S5, the insulating film IF2 is formed on the wiring WL1. In the second insulating film formation step S5, firstly, for example, by the CVD method, the materials constituting the insulating film IF2, namely, the material of the first silicon oxide film, the material of the silicon nitride film, and the material of the second silicon oxide film, are sequentially deposited on the wiring WL1, forming the insulating film IF2.

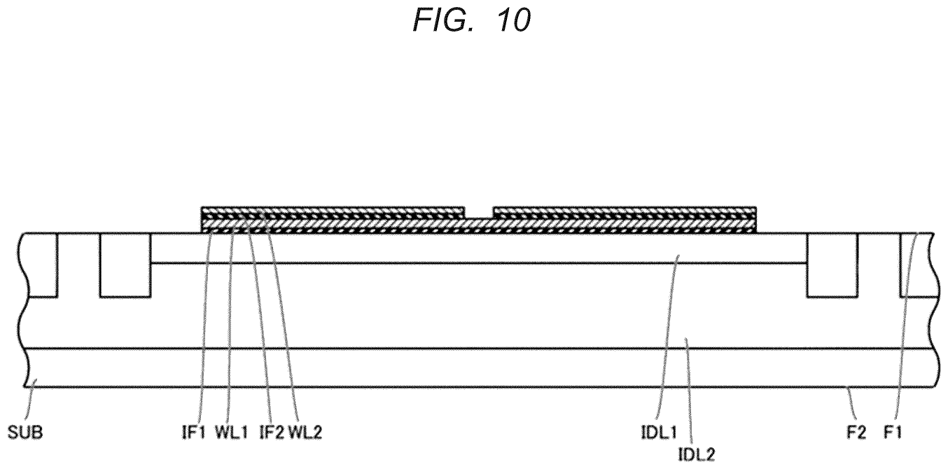

As shown in FIG. 10, in the second wiring formation step S6, the wiring WL2 is formed on the insulating film IF2. In the second wiring formation step S6, firstly, for example, by sputtering, the material constituting the wiring WL2 is formed on the insulating film IF1. Secondly, a resist pattern is formed on the material constituting the wiring WL1. The resist pattern is formed by applying photoresist on the material constituting the wiring WL1 and then exposing and developing the photoresist. Thirdly, dry etching is performed on the material constituting the wiring WL2 and the material constituting the insulating film IF2 through the openings of the resist pattern, patterning the materials constituting the wiring WL2 and the insulating film IF2, and forming the wiring WL2.

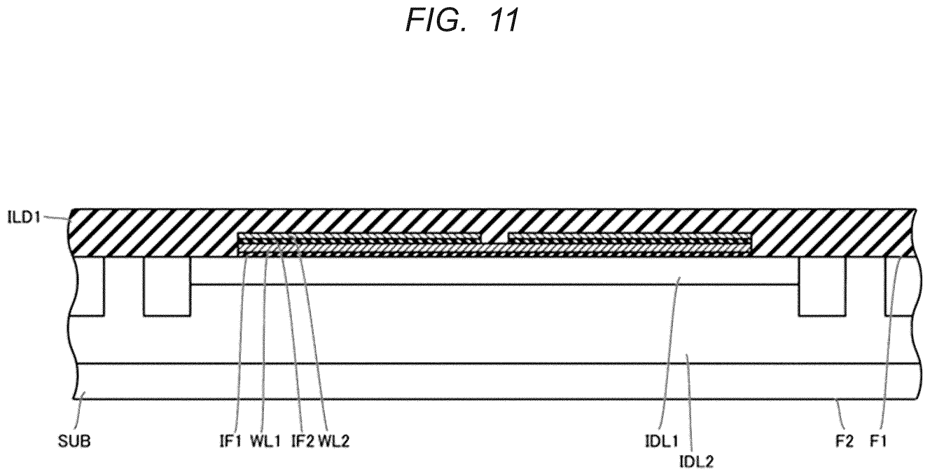

As shown in FIG. 11, in the interlayer insulating film formation step S7, the interlayer insulating film ILD1 is formed on the upper surface F1 to cover the insulating film IF1, the wiring WL1, the insulating film IF2, and the wiring WL2. In the interlayer insulating film formation step S7, firstly, for example, by the CVD method, the material constituting the interlayer insulating film ILD1 is formed on the upper surface F1 to cover the insulating film IF1, the wiring WL1, the insulating film IF2, and the wiring WL2. Secondly, the upper surface of the material constituting the interlayer insulating film ILD1 is planarized, for example, by the CMP (Chemical Mechanical Polishing) method. Thus, the interlayer insulating film ILD1 is formed.

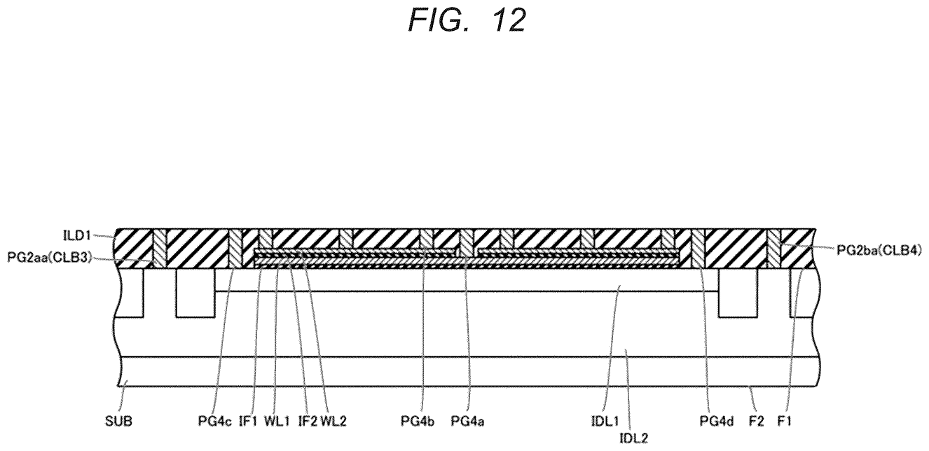

As shown in FIG. 12, in the plug formation step S8, the plug PG2aa, the plug PG2ba, the plug PG4a, the plurality of plug PG4b, the plug PG4c, and the plug PG4d are formed in the interlayer insulating film ILD1. In the plug formation step S8, firstly, a resist pattern is formed on the interlayer insulating film ILD1. The resist pattern is formed by applying photoresist on the interlayer insulating film ILD1 and then exposing and developing the photoresist. Secondly, dry etching is performed on the interlayer insulating film ILD1 through the openings of the resist pattern, forming a plurality of through-holes in the interlayer insulating film ILD1. Thirdly, for example, by the CVD method, the material constituting the plug PG2aa or the like is embedded in the plurality of through-holes, and the material constituting the plug PG2aa or the like is formed on the interlayer insulating film ILD1. Fourthly, the material constituting the plug PG2aa or the like formed outside the plurality of through-holes is removed, for example, by the CMP method. Thus, the plug PG2aa, the plug PG2ba, the plug PG4a, the plurality of plugs PG4b, the plug PG4c, and the plug PG4d are formed.

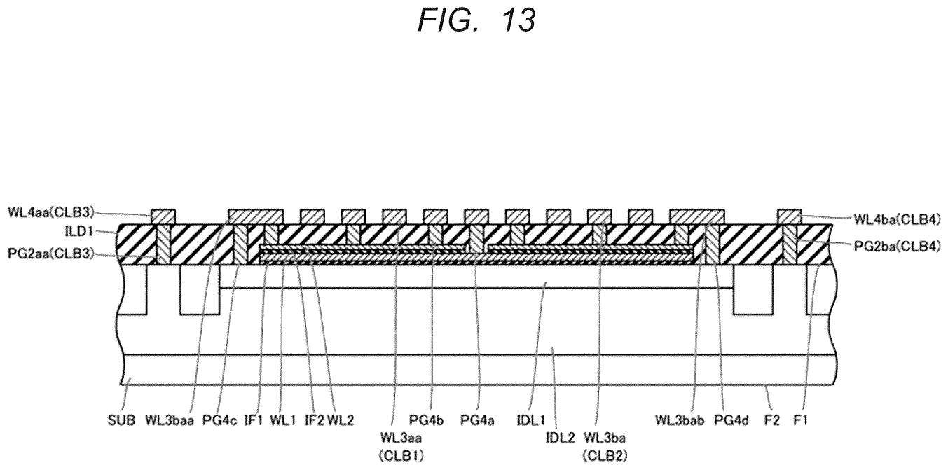

As shown in FIG. 13, in the third wiring formation step S9, the plurality of wirings WL3aa, the plurality of wirings WL3ba, the wiring WL4aa, and the wiring WL4ba are formed on the interlayer insulating film ILD1. In the third wiring formation step S9, firstly, for example, by the sputtering method, the material constituting the wiring WL3aa or the like is formed on the interlayer insulating film ILD1. Secondly, a resist pattern is formed on the material constituting the wiring WL2aa or the like. Thirdly, dry etching is performed on the material constituting the wiring WL2aa or the like through the openings of the resist pattern, patterning the material constituting the wiring WL2aa or the like, and forming the plurality of wirings WL3aa, the plurality of wirings WL3ba, the wiring WL4aa, and the wiring WL4ba.

By repeating steps similar to the interlayer insulating film formation step S7, the plug formation step S8, and the third wiring formation step S9, the wiring, the interlayer insulating films, and the plurality of pads PD positioned over the wirings WL3aa, the plurality of wirings WL3ba, the wiring WL4aa, and the wiring WL4ba are formed. Subsequently, by performing the singulation step S10, the structure of the semiconductor device DEV1 shown in FIG. 1 and FIG. 2 is formed.

### Modified Example

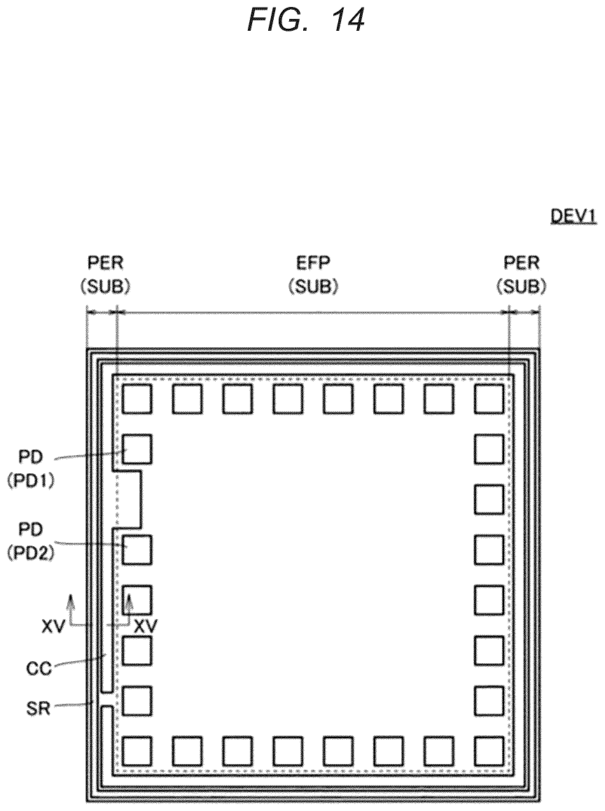

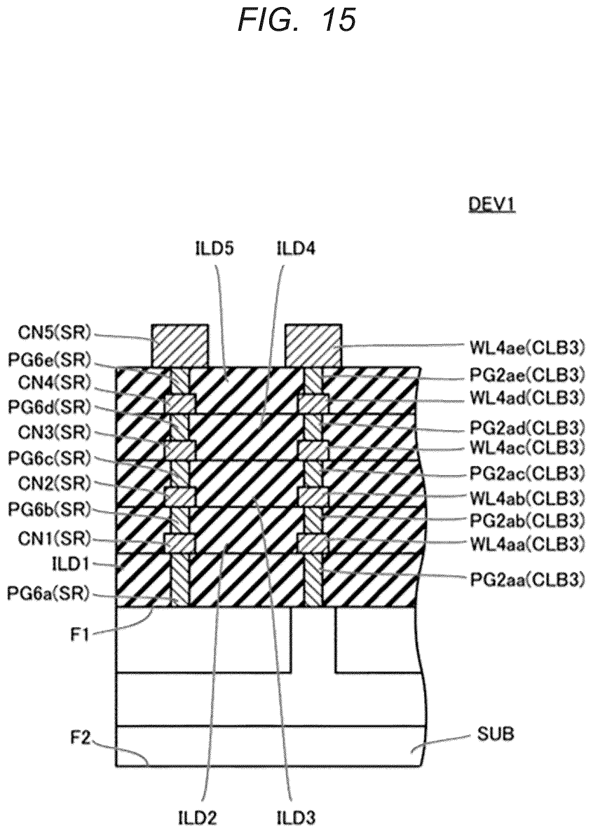

As shown in FIG. 14 and FIG. 15, the semiconductor device DEV1 may further include a seal ring SR. The seal ring SR surrounds the composite capacitor CC in plan view. That is, the seal ring SR is formed outside the conductive laminate CLB1 in plan view. The seal ring SR includes a conductor CN1, a conductor CN2, a conductor CN3, a conductor CN4, and a conductor CN5, and a plug PG6a, a plug PG6b, a plug PG6c, a plug PG6d, and a plug PG6e.

The conductor CN1 is formed on the interlayer insulating film ILD1 and covered by the interlayer insulating film ILD2. The conductor CN2 is formed on the interlayer insulating film ILD2 and covered by the interlayer insulating film ILD3. The conductor CN3 is formed on the interlayer insulating film ILD3 and covered by the interlayer insulating film ILD4. The conductor CN4 is formed on the interlayer insulating film ILD4 and covered by the interlayer insulating film ILD5. The conductor CN5 is formed on the interlayer insulating film ILD1. The conductor CN1, the conductor CN2, the conductor CN3, the conductor CN4, and the conductor CN5 overlap each other in plan view and extend along the peripheral portion PER in plan view. The conductor CN1, the conductor CN2, the conductor CN3, the conductor CN4, and the conductor CN5 are formed, for example, of aluminum or aluminum alloy.

The plug PG6a is formed in the interlayer dielectric film ILD1. The plug PG6b is formed in the interlayer dielectric film ILD2. The plug PG6c is formed in the interlayer dielectric film ILD3. The plug PG6d is formed in the interlayer dielectric film ILD4. The plug PG6e is formed in the interlayer dielectric film ILD5. The plug PG6a, the plug PG6b, the plug PG6c, the plug PG6d, and the plug PG6e overlap each other in plan view and extend along the outer peripheral portion PER.

The plug PG6a is positioned between the upper surface F1 and the conductor CN1, connecting the upper surface F1 and the conductor CN1. The plug PG6b is positioned between the conductor CN1 and the conductor CN2, connecting the conductor CN1 and the conductor CN2. The plug PG6c is positioned between the conductor CN2 and the conductor CN3, connecting the conductor CN2 and the conductor CN3. The plug PG6d is positioned between the conductor CN3 and the conductor CN4, connecting the conductor CN3 and the conductor CN4. The plug PG6e is positioned between the conductor CN4 and the conductor CN5, connecting the conductor CN4 and the conductor CN5.

### Effects of Semiconductor Device DEV1

When attempting to omit the external attachment of high-capacity capacitors such as bootstrap capacitors BSC, it is necessary to monolithically form a plurality of capacitor elements in semiconductor device DEV1. However, if a plurality of capacitor elements are formed inside the outer peripheral edge of the element formation portion EFP in plan view, the area of the element formation portion EFP in plan view increases, leading to an increase in the chip area of the semiconductor device DEV1.

In this regard, in the semiconductor device DEV1, the composite capacitor CC is formed to surround the element formation portion EFP in plan view. That is, in the semiconductor device DEV1, the composite capacitor CC is formed to overlap the outer peripheral portion PER in plan view. Since no circuit elements are formed at positions overlapping the outer peripheral portion PER in plan view, according to the semiconductor device DEV1, the area of the element formation portion EFP is not constrained by the composite capacitor CC, and the increase in chip area can be suppressed.

A trench capacitor includes a trench formed at an upper surface of a semiconductor substrate, a well layer formed in the semiconductor substrate surrounding the trench, a polysilicon layer formed in the trench, and an insulating film interposed between the polysilicon layer and the inner wall surface and the bottom surface of the trench. Forming such a trench capacitor requires special processes, so if a plurality of trench capacitors are formed instead of the composite capacitor CC, manufacturing costs increase.

A planar MOS capacitor includes a well layer formed in the semiconductor substrate and positioned at the upper surface of the semiconductor substrate, an insulating film formed on the upper surface of the semiconductor substrate to overlap the well layer in plan view, and a polysilicon layer formed on the insulating film. Compared to trench capacitors, the planar MOS capacitors have a smaller capacitance per unit area. Additionally, to prevent malfunction due to capacitive coupling, a wiring cannot be placed over the planar MOS capacitor. Therefore, if a plurality of planar MOS capacitors are formed instead of the composite capacitor CC, the chip area increases, reducing the number of chips obtained from a single wafer, thus increasing manufacturing costs.

The composite capacitor CC is formed during the step of forming impurity diffusion layers, wirings, and plugs that configure circuit elements other than the composite capacitor CC, so no special process is required to form the composite capacitor CC. In the composite capacitor CC, the capacitor element C1, the capacitor element C2, the capacitor element C3, and the capacitor element C4 are connected in parallel. Additionally, since the wiring configuring circuit elements other than the composite capacitor CC does not cross the outer peripheral portion PER in plan view, the wiring, the impurity diffusion layers, and the plugs at positions overlapping the outer peripheral portion PER in plan view can be effectively utilized as capacitance resources. As a result, the composite capacitor CC can increase the capacitance per unit area, and the increase in manufacturing costs of semiconductor device DEV1 can be suppressed.

In the semiconductor device DEV1, the conductive laminate CLB3 not only supplies potential to the impurity diffusion layer IDL2 but also serves to stop the propagation of cracks during dicing, allowing the chip area to be further reduced by omitting the seal ring SR. Even if damage occurs to the conductive laminate CLB3 due to crack propagation, potential can still be supplied from the conductive laminate CLB4 to the impurity diffusion layer IDL2, securing the function of the composite capacitor CC despite damage to the conductive laminate CLB3.

In the semiconductor device DEV1, since the composite capacitor CC is formed to overlap the outer peripheral portion PER in plan view, the distance from the junction capacitor CC to the connection destination of the composite capacitor CC, i.e., the distance from the junction capacitor CC to the analog circuit block ACB, is short. Therefore, in the semiconductor device DEV1, the routing wiring between the composite capacitor CC and the analog circuit block ACB can be shortened.

While the analog circuit block ACB1 is prone to becoming a noise source, the analog circuit block ACB2 is sensitive to noise. Therefore, if the part of the composite capacitor CC surrounding the analog circuit block ACB1 in plan view is separated from the part of the composite capacitor CC surrounding the analog circuit block ACB2 in plan view, noise generated in the analog circuit block ACB1 is less likely to propagate to the analog circuit block ACB2 via the composite capacitor CC. Additionally, if the junction capacitor CC is divided at a location facing the analog circuit block ACB2, the distance that noise generated in the analog circuit block ACB1 propagates through the junction capacitor CC to reach the analog circuit block ACB2 becomes longer, reducing the impact of noise generated in the analog circuit block ACB1 on the analog circuit block ACB2.

If part of the composite capacitor CC is positioned between the pad PD1 and the pad PD2 in plan view, the area of the composite capacitor CC in plan view becomes even larger, and the capacitance of the composite capacitor CC increases further.

### Second Embodiment

The semiconductor device DEV2 according to the second embodiment will be described. Here, the differences from the semiconductor device DEV1 will be mainly explained, and repetitive descriptions will not be repeated.

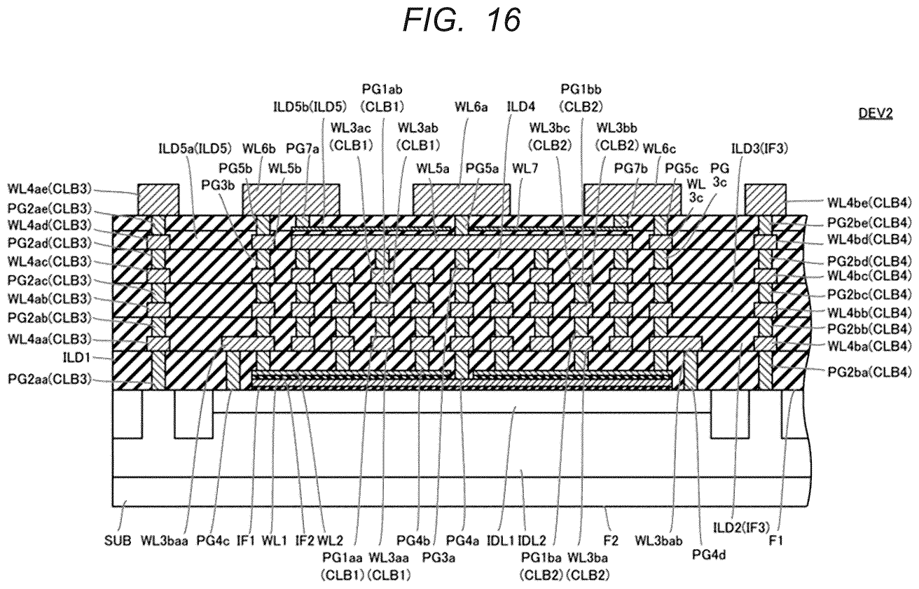

As shown in FIG. 16, in the semiconductor device DEV2, the interlayer insulating film ILD5 includes a first layer ILD5a and a second layer ILD5b. The first layer ILD5a is formed on the interlayer insulating film ILD4 to cover the wiring WL5a, the wiring WL5b, the wiring WL5c, the wiring WL4ae, and the wiring WL4be. The second layer ILD5b is formed on the first layer ILD5a. The semiconductor device DEV2 further includes a wiring WL7. The wiring WL7 is formed on the first layer ILD5a and is covered by the second layer ILD5b. From another perspective, a part of the first layer ILD5a is positioned between the wiring WL5a and the wiring WL7. The wiring WL7 is formed, for example, of titanium nitride.

The semiconductor device DEV2 further includes a plug PG7a and a plug PG7b. The plug PG7a and the plug PG7b are formed in the second layer ILD5b. The wiring WL6b partially overlaps the wiring WL7 in plan view. The wiring WL6c partially overlaps the wiring WL7 in plan view. The plug PG7a is positioned between the wiring WL6b and the wiring WL7, connecting the wiring WL6b and the wiring WL7. The plug PG7b is positioned between the wiring WL6c and the wiring WL7, connecting the wiring WL6c and the wiring WL7. The plug PG7a and the plug PG7b are formed, for example, of tungsten.

In the manufacturing method of the semiconductor device DEV2, the step up to forming the wiring WL5a, the wiring WL5b, the wiring WL5c, the wiring WL4ae, and the wiring WL4be on the interlayer insulating film ILD4 is the same as the manufacturing method of the semiconductor device DEV1.

The first layer ILD5a is formed after the wiring WL5a, the wiring WL5b, the wiring WL5c, the wiring WL4ae, and the wiring WL4be. During the formation of the first layer ILD5a, firstly, for example, by the CVD method, the material of the first layer ILD5a is formed on the interlayer insulating film ILD4 to cover the wiring WL5a, the wiring WL5b, the wiring WL5c, the wiring WL4ae, and the wiring WL4be. Secondly, the upper surface of the material of the formed first layer ILD5a is planarized, for example, by the CMP method. Thus, the first layer ILD5a is formed.

During the formation of the wiring WL7, firstly, after the first layer ILD5a is formed, for example, by the sputtering method, the material of the wiring WL7 is formed on the first layer ILD5a. Secondly, a resist pattern is formed on the material of the wiring WL7. The resist pattern is formed by applying photoresist on the material of the wiring WL7 and then exposing and developing the photoresist. Thirdly, dry etching is performed on the material of the wiring WL7 through the openings of the resist pattern, patterning the material of the wiring WL7 and forming the wiring WL7.

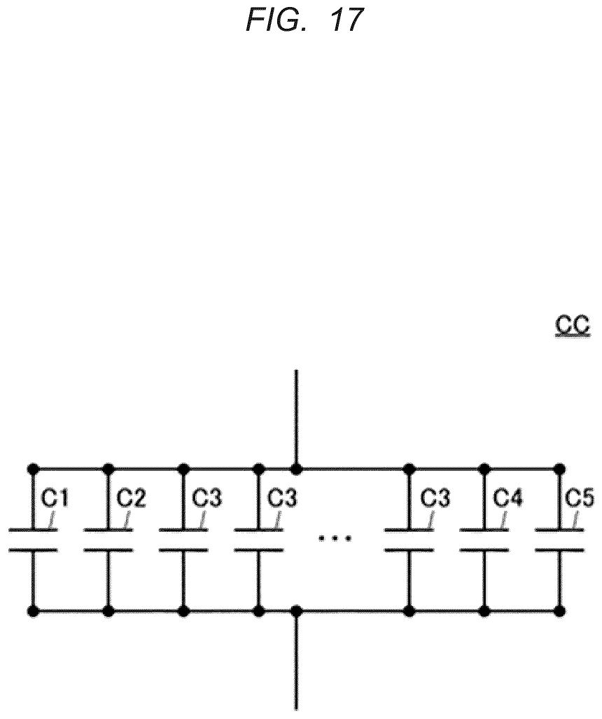

During the formation of the second layer ILD5b, firstly, after the wiring WL7 is formed, for example, by the CVD method, the material of the second layer ILD5b is formed on the first layer ILD5a to cover the wiring WL7. Secondly, the upper surface of the material of the formed second layer ILD5b is planarized, for example, by the CMP method. Thus, the second layer ILD5b is formed. Subsequent steps are carried out in the same manner as the manufacturing method of the semiconductor device DEV1, forming the structure of the semiconductor device DEV2 as shown in FIG. 17.

As shown in FIG. 17, in the semiconductor device DEV2, the composite capacitor CC, in addition to the capacitor element C1, the capacitor element C2, the capacitor element C3, and the capacitor element C4, further includes a capacitor element C5. The capacitor element C5 is connected in parallel with the capacitor element C1, the capacitor element C2, the capacitor element C3, and the capacitor element C4. The capacitor element C5 includes the wiring WL5a, the wiring WL7, and the first layer ILD5a.

With the formation of the capacitor element C5, the area of composite capacitor CC in plan view does not increase compared to when the capacitor element C5 is not formed. Therefore, according to the semiconductor device DEV2, the capacitance of the composite capacitor CC per unit area can be further increased.

Although the invention made by the inventor has been specifically described based on the embodiment, it is needless to say that the present invention is not limited to the above embodiment and various modifications can be made without departing from the gist thereof.

What is claimed is:

1. A semiconductor device comprising:
a semiconductor substrate having an element formation portion; and
a composite capacitor formed to surround the element formation portion in plan view,
wherein the composite capacitor has a plurality of capacitor elements electrically connected in parallel.

2. The semiconductor device according to claim 1,
wherein the semiconductor substrate has an upper surface, and
wherein a first capacitor element of the plurality of capacitor elements comprises:
a first impurity diffusion layer formed in the semiconductor substrate and disposed at the upper surface;
a first insulating film formed on the upper surface to overlap the first impurity diffusion layer in plan view; and
a first wiring formed on the first insulating film.

3. The semiconductor device according to claim 2,
wherein the first wiring is formed of polycrystalline silicon.

4. The semiconductor device according to claim 1,
wherein the semiconductor substrate has an upper surface, and
wherein a second capacitor element of the plurality of capacitor elements comprises:
a first wiring formed over the upper surface;
a second insulating film formed on the first wiring; and
a second wiring formed on the second insulating film.

5. The semiconductor device according to claim 4,
wherein the first wiring is formed of polycrystalline silicon,
wherein the second insulating film comprises:
a first silicon oxide film;
a silicon nitride film formed on the first silicon oxide film; and
a second silicon oxide film formed on the silicon nitride film, and
wherein the second wiring is formed of metal silicide.

6. The semiconductor device according to claim 1,
wherein the semiconductor substrate has an upper surface,
wherein the semiconductor substrate has an outer peripheral portion surrounding the element formation portion in plan view,
wherein a third capacitor element of the plurality of capacitor elements comprises:
a third insulating film formed over the upper surface;
a first conductive laminate formed in the third insulating film; and
a second conductive laminate formed in the third insulating film, the second conductive laminate facing the first conductive laminate via a part of the third insulating film in a direction from an inner peripheral edge of the outer peripheral portion to an outer peripheral edge of the outer peripheral portion,
wherein the first conductive laminate has a plurality of third wirings and a plurality of first plugs,
wherein the plurality of third wirings are laminated such that one of the plurality of first plugs is positioned between two of the plurality of third wirings adjacent to each other,
wherein the second conductive laminate has a plurality of fourth wirings and a plurality of second plugs, and
wherein the plurality of fourth wirings are laminated such that one of the plurality of second plugs is positioned between two of the plurality of fourth wirings adjacent to each other.

7. The semiconductor device according to claim 1,
wherein the semiconductor substrate has an upper surface,
wherein a fourth capacitor element of the plurality of capacitor elements comprises:
a first impurity diffusion layer formed in the semiconductor substrate and disposed at the upper surface; and
a second impurity diffusion layer formed in the semiconductor substrate and disposed under the first impurity diffusion layer to contact the first impurity diffusion layer, and
wherein a conductivity type of the first impurity diffusion layer is opposite to a conductivity type of the second impurity diffusion layer.

8. The semiconductor device according to claim 1,
wherein the semiconductor substrate has an upper surface; and
wherein a fifth capacitor element of the plurality of capacitor elements comprises:
a fifth wiring formed over the upper surface;
a fourth insulating film formed on the fifth wiring; and
a sixth wiring formed on the fourth insulating film.

9. The semiconductor device according to claim 8,
wherein the fifth wiring is formed of aluminum or an aluminum alloy, and
wherein the sixth wiring is formed of titanium nitride.

10. The semiconductor device according to claim 1, further comprising:
a third conductive laminate electrically connected to the plurality of capacitor elements,
wherein the semiconductor substrate has an upper surface,
wherein the third conductive laminate is formed on the upper surface and has a plurality of seventh wirings and a plurality of third plugs, and
wherein the plurality of seventh wirings are laminated such that one of the plurality of third plugs is positioned between two of the plurality of seventh wirings adjacent to each other and between the upper surface and one of the plurality of seventh wirings positioned at the lowermost layer.

11. The semiconductor device according to claim 10,
wherein the third conductive laminate surrounds the composite capacitor in plan view.

12. The semiconductor device according to claim 11, further comprising:
a fourth conductive laminate electrically connected to the plurality of capacitor elements,
wherein the fourth conductive laminate is formed on the upper surface and has a plurality of eighth wirings and a plurality of fourth plugs,
wherein the plurality of eighth wirings are laminated such that one of the plurality of fourth plugs is positioned between two of the plurality of eighth wirings adjacent to each other and between the upper surface and one of the plurality of eighth wirings positioned at the lowermost layer, and
wherein the fourth conductive laminate is surrounded by the composite capacitor and surrounds the element formation portion in plan view.

13. The semiconductor device according to claim 1, further comprising:
a seal ring,
wherein the seal ring surrounds the composite capacitor in plan view.

14. The semiconductor device according to claim 1, further comprising:
a plurality of bonding pads,
wherein the plurality of bonding pads are arranged in a row along an outer peripheral edge of the element formation portion in plan view, and
wherein the plurality of bonding pads comprises:
a first bonding pad; and
a second bonding pad arranged adjacent to and separated from the first bonding pad, and
wherein a part of the composite capacitor is positioned between the first bonding pad and the second bonding pad in plan view.

15. The semiconductor device according to claim 1, further comprising:
a plurality of bonding pads,
wherein the plurality of bonding pads are arranged in a row along an outer peripheral edge of the element formation portion in plan view, and
wherein a part of the composite capacitor is formed under the plurality of bonding pads to overlap the plurality of bonding pads in plan view.

16. The semiconductor device according to claim 1,
wherein the element formation portion has an analog circuit block positioned at an outer peripheral portion of the element formation portion in plan view, and an analog circuit is formed in the analog circuit block, and
wherein the composite capacitor is electrically connected to the analog circuit block.

17. The semiconductor device according to claim 16,
wherein the composite capacitor is divided at least at one location facing the analog circuit block in plan view.
